(19) United States
(12) Patent Application Publication
(10) Pub. No.: US 2006/0043394 A1
(43) Pub. Date: Mar. 2, 2006

(54) Gallium-nitride based light emitting diode structure

(76) Inventors: Liang-Wen Wu, Banciao City (TW); Ru-Chin Tu, Tainan City (TW); Cheng-Tsang Yu, Wufong Township (TW); Tzu-Chi Wen, Tainan City (TW); Fen-Ren Chien, Yonghe City (TW)

Correspondence Address: SUPREME PATENT SERVICES, P.O. BOX 2339, SARATOGA, CA, 95070-0339, US

(21) Appl. No.: 10/932,802

(22) Filed: Sep. 1, 2004

(51) Int. Cl. H01L 33/00

(52) U.S. Cl. 257/94

(57) ABSTRACT

A gallium-nitride(GaN) based light emitting diode (LED) structure utilizing materials having compatible lattice constant is provided. When aluminum-indium-nitride (AlₓIn₁₋ₓN, 0<x<1) is used to make the p-type cladding layer within the GaN-based LED structure, the cladding layer has a lattice constant compatible with that of GaN. The active layer's multi-quantum well (MQW) structure, therefore, would not be damaged from the excessive stress resulted from the incompatible lattice constant during the GaN-based LED's epitaxial growth. In addition, AlₓIn₁₋ₓN (0<x<1) has a wider band gap than that of GaN, which can prevent electrons from overflowing from the MQW active layer. This, in turn, will increase the possibility of forming electron-hole pairs within the MQW active layer. Also due to its wider band gap, AlₓIn₁₋ₓN (0<x<1) has an effective confinement effect on the photons, which again will increase the GaN-based LED's lighting efficiency. Besides, AlₓIn₁₋ₓN (0<x<1) has a lower growing temperature so that the MQW active layer would remain intact during the low-temperature growth of the cladding layer, which, again, would increase the GaN-based LED's lighting efficiency.

### BACKGROUND OF THE INVENTION

1. Field of the Invention

The present invention relates to the gallium-nitride (GaN) based light emitting diode (LED), and in particular to the epitaxy structure of the GaN-based LED.

2. The Prior Arts

Conventionally, a GaN-based LED utilizing indium-gallium-nitride (InGaN) multi-quantum wells (MQWs) technology usually employs a structure whose InGaN MQW active layer is covered and protected by a p-type aluminum-gallium-nitride (AlGaN) cladding layer. Based on the observation from practical operations, however, such a structure has a number of disadvantages. The two severest ones are as follows. First, the lattice constant of the p-type AlGaN cladding layer is very much different from that of the InGaN MQW active layer. Such a significant difference in lattice constants, due to the piezoelectric field effect, would easily cause a stress so strong that the light emitting characteristics of the LED's epitaxy structure is affected. In the worse case, the epitaxy structure itself would be damaged. Secondly, the p-type AlGaN cladding layer would have a better epitaxy structure only when it is grown under a temperature above 1000° C. However, the InGaN MQW active layer is best grown under a temperature between 700° C. and 800° C. Therefore, when the growing temperature is raised above 1000° C. for the p-type AlGaN cladding layer, the InGaN MQW active layer's MQW structure would be damaged, which in turn would affect the lighting efficiency of the GaN-based LED.

### SUMMARY OF THE INVENTION

To overcome the foregoing disadvantages, the present invention provides a GaN-based LED structure utilizing lattice constant matching technology. The new structure provided by the present invention achieves numerous advantages over the existing GaN-based LED structure according to prior arts.

The principal idea behind the present invention can be best explained with FIG. 1. FIG. 1 shows the band gaps and the lattice constants of group III nitrides when applied in GaN-based LEDs. As shown in FIG. 1, group III nitrides have a broad band gap coverage. For example, indium-nitride (InN) has a band gap as low as 0.7 eV (Eg_{(InN)}=0.7 eV), GaN has a band gap 3.4 eV (Eg_{(GaN)}=3.4 eV), and aluminum-nitride (AlN) has a band gap as high as 6.3 eV (Eg_{(AlN)}=6.3 eV). The LEDs made by an appropriate choice of group III nitrides are therefore capable of emitting lights from red lights to ultra-violet lights. As also shown in FIG. 1, GaN has a lattice constant 3.18 Å. By extending a lattice matching line from GaN, it can be seen that an aluminum-indium-nitride (AlₓIn₁₋ₓN, 0<x<1) with a specific composition would have a lattice constant compatible with that of GaN.

The purpose of the present invention, therefore, is to use an AlₓIn₁₋ₓN (0<x<1) material as the p-type cladding layer so that the p-type cladding layer has a lattice constant compatible with that of GaN. The active layer's MQW structure, therefore, would not be damaged from the excessive stress resulted from the incompatible lattice constants during the epitaxial growth of the p-type cladding layer. In addition, another purpose of the present invention can also be seen clearly from FIG. 1. As shown in FIG. 1, the AlₓIn₁₋ₓN (0<x<1) having a specific composition possesses a wider band gap than that of GaN. The p-type cladding layer made by such an AlₓIn₁₋ₓN (0<x<1) material can prevent electrons from overflowing which, in turn, will increase the possibility of forming electron-hole pairs within the MQW active layer. The p-type cladding layer made by such an AlₓIn₁₋ₓN (0<x<1) material, due to its wider band gap, has an effective confinement effect on the photons, which in turn will increase the GaN-based LED's lighting efficiency. The third purpose of the present invention is that the p-type cladding layer made by such an AlₓIn₁₋ₓN (0<x<1) material has a lower growing temperature than the existing p-type AlGaN cladding layer. The InGaN active layer would therefore remain intact during the growth of the p-type cladding layer, which, again, would increase the GaN-based LED's lighting efficiency.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 shows the band gaps and the lattice constants of group III nitrides when applied in GaN-based LEDs.

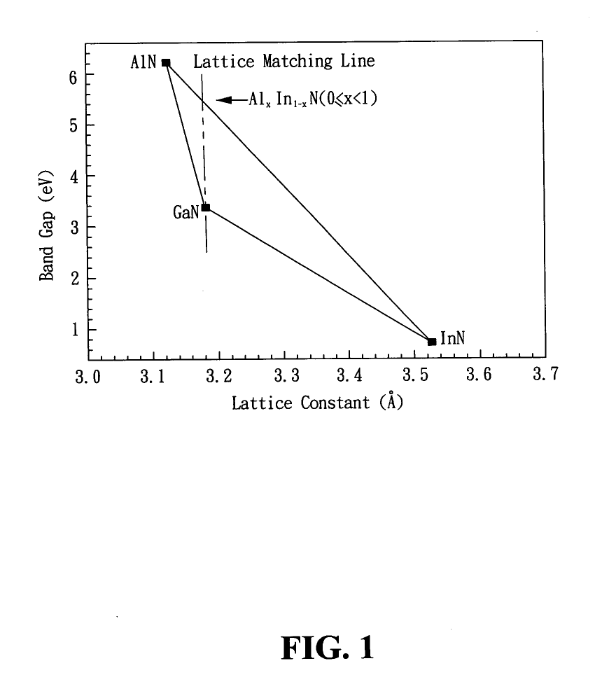

FIG. 2 is a schematic diagram showing the GaN-based LED structure according to the first embodiment of the present invention.

FIG. 3 is a schematic diagram showing the GaN-based LED structure according to the second embodiment of the present invention.

FIG. 4 is a schematic diagram showing the GaN-based LED structure according to the third embodiment of the present invention.

FIG. 5 is a schematic diagram showing the GaN-based LED structure according to the fourth embodiment of the present invention.

### DETAILED DESCRIPTION OF THE PREFERRED EMBODIMENTS

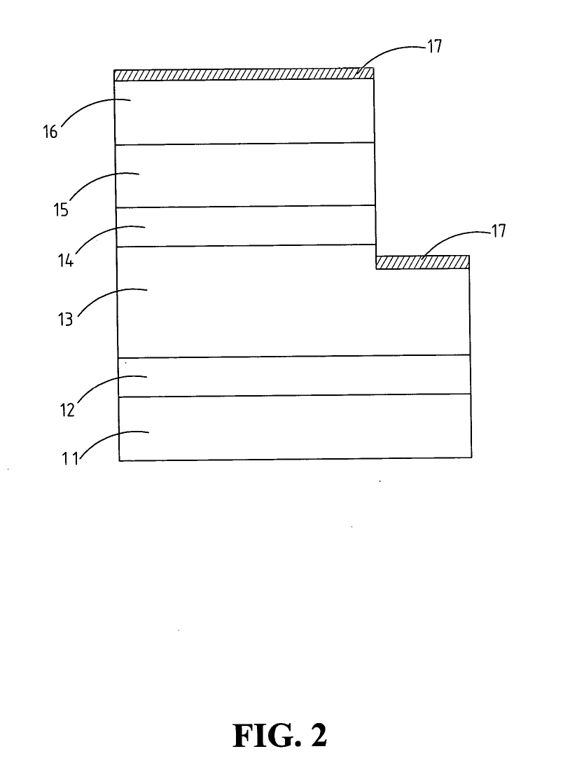

FIG. 2 is a schematic diagram showing the GaN-based LED structure according to the first embodiment of the present invention.

As shown in FIG. 2, the GaN-based LED structure contains a substrate 11, a buffer layer 12, a n-type GaN contact layer 13, an active layer 14, a p-type cladding layer 15, and a p-type contact layer 16.

The substrate 11 is made of sapphire (aluminum-oxide monocrystalline). The buffer layer 12 is located upon the substrate 11 and is made of aluminum-gallium-indium-nitride (Al_{1-a-b}GaₐIn_{b}N, 0≦a, b<1). The n-type GaN contact layer 13 is located upon the buffer layer 12. The active layer 14 is located upon the n-type GaN contact layer 13 and is made of InGaN. The p-type cladding layer 15 on top of the active layer 14 is made of magnesium (Mg)-doped Al_{1-c}In_{c}N (0<c<1) and has a thickness between 50 Å and 3000 Å. The p-type cladding layer 15 is grown under a temperature between 600° C. and 1200° C.

The p-type contact layer 16 on top of the p-type cladding layer 15 is made of Mg-doped GaN.

As shown in FIG. 2, the GaN-based LED structure according to the first embodiment of the present invention can further contain an electrode layer 17 on top of the p-type contact layer 16 or the n-type GaN contact layer 13.

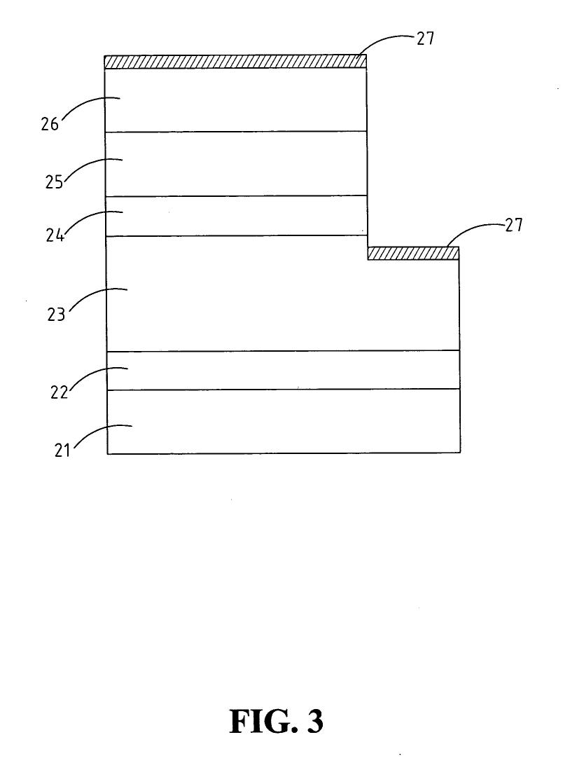

FIG. 3 is a schematic diagram showing the GaN-based LED structure according to the second embodiment of the present invention.

As shown in FIG. 3, the GaN-based LED structure contains a substrate 21, a buffer layer 22, a n-type GaN contact layer 23, an active layer 24, a p-type cladding layer 25, and a p-type contact layer 26.

The substrate 21 is made of sapphire (aluminum-oxide monocrystalline). The buffer layer 22 is located upon the substrate 21 and is made of Al_{1-d-e}Ga_{d}InₑN (0≦d, e<1). The n-type GaN contact layer 23 is located upon the buffer layer 22. The active layer 24 is located upon the n-type GaN contact layer 23 and is made of InGaN. The p-type cladding layer 25 on top of the active layer 24 is made of Al_{1-f}In_{f}N (0<f<1) doped with Mg and Ga, and has a thickness between 50 Å and 3000 Å. The p-type cladding layer 25 is grown under a temperature between 600° C. and 1200° C.

The p-type contact layer 26 on top of the p-type cladding layer 25 is made of Mg-doped GaN.

As shown in FIG. 3, the GaN-based LED structure according to the second embodiment of the present invention can further contain an electrode layer 27 on top of the p-type contact layer 26 or the n-type GaN contact layer 23.

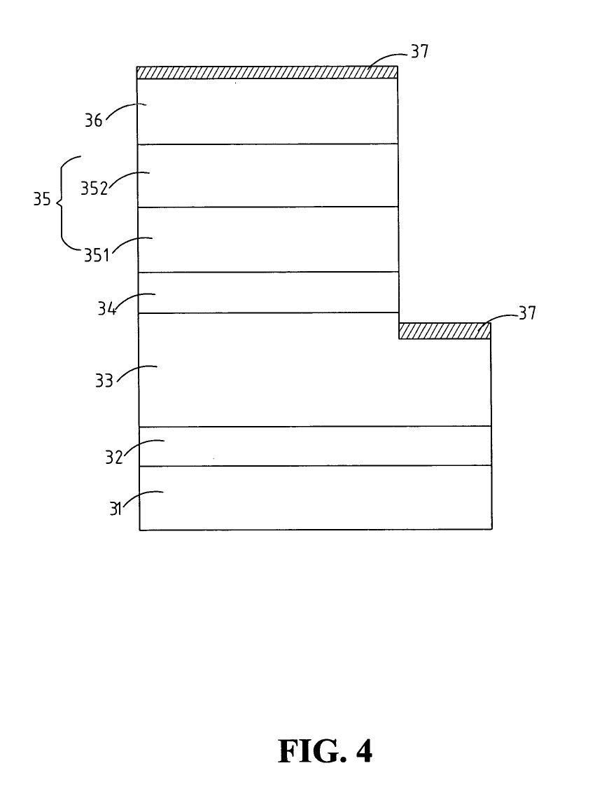

FIG. 4 is a schematic diagram showing the GaN-based LED structure according to the third embodiment of the present invention.

As shown in FIG. 4, the GaN-based LED structure contains a substrate 31, a buffer layer 32, a n-type GaN contact layer 33, an active layer 34, a p-type double cladding layer 35, and a p-type contact layer 36.

The substrate 31 is made of sapphire (aluminum-oxide monocrystalline). The buffer layer 32 is located upon the substrate 31 and is made of Al_{1-g-h}Ga_{g}InₕN (0≦g, h<1). The n-type GaN contact layer 33 is located upon the buffer layer 32. The active layer 34 is located upon the n-type GaN contact layer 33 and is made of InGaN. The p-type double cladding layer 35 on top of the active layer 34 further contains a first cladding layer 351 and a second cladding layer 352. The first cladding layer 351 on top of the active layer 34 is made of Al₁₋ᵢInᵢN (0<i<1) doped with Mg and Ga, and has a thickness between 50 Å and 3000 Å. The first cladding layer 351 is grown under a temperature between 600° C. and 1200° C. The second cladding layer 352 on top of the first cladding layer 351 is made of Mg-doped Al₁₋ⱼInⱼN (0<j<1) and has a thickness between 50 Å and 3000 Å. The second cladding layer 352 is grown under a temperature between 600° C. and 1200° C.

The p-type contact layer 36 on top of the p-type double cladding layer 35 is made of Mg-doped GaN.

As shown in FIG. 4, the GaN-based LED structure according to the third embodiment of the present invention can further contain an electrode layer 37 on top of the p-type contact layer 36 or the n-type GaN contact layer 33.

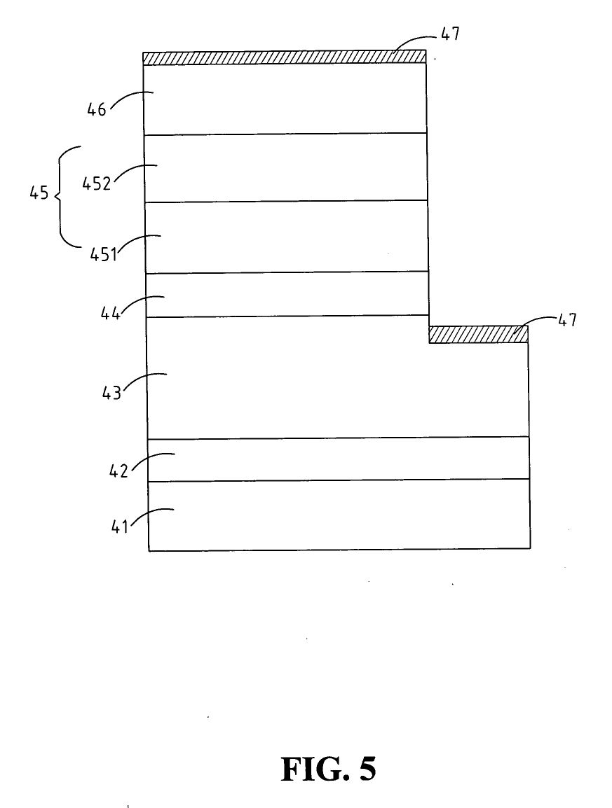

FIG. 5 is a schematic diagram showing the GaN-based LED structure according to the fourth embodiment of the present invention.

As shown in FIG. 5, the GaN-based LED structure contains a substrate 41, a buffer layer 42, a n-type GaN contact layer 43, an active layer 44, a p-type double cladding layer 45, and a p-type contact layer 46.

The substrate 41 is made of sapphire (aluminum-oxide monocrystalline). The buffer layer 42 is located upon the substrate 41 and is made of Al₁₋ₖ₋ₗGaₖInₗN (0≦k, l<1). The n-type GaN contact layer 43 is located upon the buffer layer 42. The active layer 44 is located upon the n-type GaN contact layer 43 and is made of InGaN. The p-type double cladding layer 45 on top of the active layer 44 further contains a first cladding layer 451 and a second cladding layer 452. The first cladding layer 451 on top of the active layer 44 is made of Mg-doped Al₁₋ₘInₘN (0<m<1) and has a thickness between 50 Å and 3000 Å. The first cladding layer 451 is grown under a temperature between 600° C. and 1200° C. The second cladding layer 452 on top of the first cladding layer 451 is made of Al₁₋ₙInₙN (0<n<1) doped with Mg and Ga, and has a thickness between 50 Å and 3000 Å. The second cladding layer 452 is grown under a temperature between 600° C. and 1200° C.

The p-type contact layer 46 on top of the p-type double cladding layer 45 is made of Mg-doped GaN.

As shown in FIG. 5, the GaN-based LED structure according to the fourth embodiment of the present invention can further contain an electrode layer 47 on top of the p-type contact layer 46 or the n-type GaN contact layer 43.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A gallium-nitride (GaN) based light emitting diode (LED) structure, comprising:
a substrate made of sapphire (aluminum-oxide monocrystalline);
a buffer layer located on top of said substrate and made of aluminum-gallium-indium-nitride (Al_{1-a-b}GaₐIn_{b}N, 0≦a, b<1);
a n-type gallium-nitride (GaN) contact layer located on top of said buffer layer;
an active layer located on top of said n-type GaN contact layer and made of indium-gallium-nitride (InGaN);
a p-type cladding layer located on top of said active layer and made of magnesium (Mg)-doped aluminum-indium-nitride (Al_{1-c}In_{c}N, 0<c<1); and
a p-type contact layer located on top of said p-type cladding layer and made of Mg-doped GaN.

2. The GaN-based LED structure according to claim 1, wherein said p-type cladding layer has a thickness between 50 Å and 3000 Å.

3. The GaN-based LED structure according to claim 1, wherein said p-type cladding layer is grown under a temperature between 600° C. and 1200° C.

4. The GaN-based LED structure according to claim 1 further comprising an electrode layer located on top of said p-type contact layer.

5. The GaN-based LED structure according to claim 1 further comprising an electrode layer located on top of said n-type GaN contact layer.

6. A GaN-based LED structure, comprising:
a substrate made of sapphire (aluminum-oxide monocrystalline);
a buffer layer located on top of said substrate and made of Al_{1-d-e}Ga_{d}InₑN (0≦d, e<1);
a n-type GaN contact layer located on top of said buffer layer;
an active layer located on top of said n-type GaN contact layer and made of InGaN;
a p-type cladding layer located on top of said active layer and made of Al_{1-f}In_{f}N (0<f<1) doped with Mg and Ga; and
a p-type contact layer located on top of said p-type cladding layer and made of Mg-doped GaN.

7. The GaN-based LED structure according to claim 6, wherein said p-type cladding layer has a thickness between 50 Å and 3000 Å.

8. The GaN-based LED structure according to claim 6, wherein said p-type cladding layer is grown under a temperature between 600° C. and 1200° C.

9. The GaN-based LED structure according to claim 6 further comprising an electrode layer located on top of said p-type contact layer.

10. The GaN-based LED structure according to claim 6 further comprising an electrode layer located on top of said n-type GaN contact layer.

11. A GaN-based LED structure, comprising:
a substrate made of sapphire (aluminum-oxide monocrystalline);
a buffer layer located on top of said substrate and made of Al_{1-g-h}Ga_{g}InₕN (0≦g, h<1);
a n-type GaN contact layer located on top of said buffer layer;
an active layer located on top of said n-type GaN contact layer and made of InGaN;
a p-type double cladding layer located on top of said active layer, further comprising:
a first cladding layer located on top of said active layer and made of Al₁₋ᵢInᵢN (0<i<1) doped with Mg and Ga; and
a second cladding layer located on top of said first cladding layer and made of Mg-doped Al₁₋ⱼInⱼN (0<j<1); and
a p-type contact layer located on top of said p-type cladding layer and made of Mg-doped GaN.

12. The GaN-based LED structure according to claim 11, wherein said first cladding layer has a thickness between 50 Å and 3000 Å, and is grown under a temperature between 600° C. and 1200° C.

13. The GaN-based LED structure according to claim 11, wherein said second cladding layer has a thickness between 50 Å and 3000 Å, and is grown under a temperature between 600° C. and 1200° C.

14. The GaN-based LED structure according to claim 11 further comprising an electrode layer located on top of said p-type contact layer.

15. The GaN-based LED structure according to claim 11 further comprising an electrode layer located on top of said n-type GaN contact layer.

16. A GaN-based LED structure, comprising:
a substrate made of sapphire (aluminum-oxide monocrystalline);
a buffer layer located on top of said substrate and made of Al₁₋ₖ₋ₗGaₖInₗN (0≦k, l<1);
a n-type GaN contact layer located on top of said buffer layer;
an active layer located on top of said n-type GaN contact layer and made of InGaN;
a p-type double cladding layer located on top of said active layer, further comprising:
a first cladding layer located on top of said active layer and made of Mg-doped Al₁₋ₘInₘN (0<m<1); and
a second cladding layer located on top of said first cladding layer and made of Al₁₋ₙInₙN (0<n<1) doped with Mg and Ga; and
a p-type contact layer located on top of said p-type cladding layer and made of Mg-doped GaN.

17. The GaN-based LED structure according to claim 16, wherein said first cladding layer has a thickness between 50 Å and 3000 Å, and is grown under a temperature between 600° C. and 1200° C.

18. The GaN-based LED structure according to claim 16, wherein said second cladding layer has a thickness between 50 Å and 3000 Å, and is grown under a temperature between 600° C. and 1200° C.

19. The GaN-based LED structure according to claim 16 further comprising an electrode layer located on top of said p-type contact layer.

20. The GaN-based LED structure according to claim 16 further comprising an electrode layer located on top of said n-type GaN contact layer.
